(19) United States
(12) Patent Application Publication
(10) Pub. No.: US 2015/0123173 A1
(43) Pub. Date: May 7, 2015

(54) 3D STACKED IMAGE SENSOR WITH PMOS COMPONENTS

(71) Applicant: SILICON OPTRONICS, INC., HSINCHU (TW)

(72) Inventor: Xinping He, Saratoga, CA (US)

(73) Assignee: SILICON OPTRONICS, INC., HSINCHU (TW)

(21) Appl. No.: 14/075,430

(22) Filed: Nov. 8, 2013

Related U.S. Application Data
(63) Continuation-in-part of application No. 14/070,365, filed on Nov. 1, 2013.

(51) Int. Cl. H01L 27/148; H01L 27/146

(52) U.S. Cl. CPC H01L 27/14831; H01L 27/14634
USPC 257/231

(57) ABSTRACT

An active pixel sensor comprises a sensor die and a circuit die. The sensor die comprises a plurality of pixels, wherein each pixel includes a light sensitive element and a transfer gate, a floating diffusion region, wherein the plurality of pixels include at least one reset gate. The circuit die comprises a plurality of processing and amplification circuits associated with the reset gates of the sensor die. The sensor die is interconnected with the circuit die utilizing a plurality of inter-die interconnects each coupled to a source node of a reset gate on the sensor die and a node of a processing and amplification circuit on the circuit die. The plurality of processing and amplification circuits each comprises a source follower transistor, wherein the source follower transistor uses a PMOS.

### CROSS-REFERENCE TO RELATED APPLICATION(S)

This application is a continuation in part application of U.S. patent application Ser. No. 14,070,365, entitled “3D STACKED IMAGE SENSOR”, which was filed on Nov. 1, 2013, and incorporated herein by reference.

### TECHNICAL FIELD

The present disclosure relates to image sensors, and more particularly, to a 3D stacked active pixel sensor with PMOS components.

### BACKGROUND

An active pixel sensor (APS) combines a photodiode with processing and amplification circuitry in each pixel to form an image sensor. In some implementations, the associated circuitry is implemented with four transistors, and may be referred to as a 4T APS. Such sensors are commonly found in devices such as cell phone cameras, digital cameras, and web cameras.

Smaller APS and smaller pixels are enabled by the improvements in semiconductor processing. A consequence of smaller pixel size is that the pixel's photodiode must also shrink to accommodate the smaller APS area. Less light is then able to fall on each pixel, and as a result image quality is reduced. Conventionally, stacked or vertically integrated image sensors are used, wherein a sensor die includes the photodiode portion stacked atop a circuitry die, which contains the remaining circuitry of an APS imager. In a stacked sensor configuration, the photodiode may occupy greater surface area. Manufacturing of the two dies independently allows for optimization for photodetection and electronics purposes.

The 4T APS imager may include a floating diffusion. These floating diffusion areas can cause defects or high dark current. In addition, non-standard CMOS process steps may be needed to form a diffusion area.

### SUMMARY OF THE INVENTION

According to an embodiment of the invention, an active pixel sensor comprises a sensor die and a circuit die. The sensor die comprises a plurality of pixels, wherein each pixel includes a light sensitive element and a transfer gate, a floating diffusion region, wherein the plurality of pixels include at least one reset gate. The circuit die comprises a plurality of processing and amplification circuits associated with the reset gates of the sensor die. The sensor die is interconnected with the circuit die utilizing a plurality of inter-die interconnects each coupled to a source node of a reset gate on the sensor die and a node of a processing and amplification circuit on the circuit die. The plurality of processing and amplification circuits each comprises a source follower transistor, wherein the source follower transistor uses a PMOS.

According to an embodiment of the invention, an active pixel sensor comprises a sensor die and a circuit die. The sensor die comprises a plurality of pixels, wherein each pixel includes a light sensitive element and a transfer gate, a plurality of floating diffusion regions associated with the plurality of transfer gate. The circuit die comprises a plurality of floating diffusion regions associated with a plurality of reset gate and a plurality of processing and amplification circuits. The sensor die is interconnected with the circuit die utilizing a plurality of inter-die interconnects each coupled to a drain node of a transfer gate on the sensor die and a node of a floating diffusion region on the circuit die. The plurality of processing and amplification circuits each comprises a source follower transistor, wherein the source follower transistor uses a PMOS.

### BRIEF DESCRIPTION OF THE DRAWINGS

The present invention is illustrated in an exemplary manner by the accompanying drawings. The drawings should be understood as exemplary rather than limiting, as the scope of the invention is defined by the claims.

FIG. 1 is a plan view of a sensor die included in an image sensor having two stacked semiconductor dies according to an embodiment of the invention.

FIG. 2 is a cross-sectional view of two stacked semiconductor dies forming an image sensor of FIG. 1.

FIG. 3A is a schematic diagram showing a structure of stacked image sensor with a floating diffusion region in a sensor die according an embodiment of the invention.

FIG. 3B is a schematic of a stacked image sensor in accordance with another embodiment of the invention.

FIG. 4 is a schematic of a stacked image sensor in accordance with another embodiment of the invention.

FIG. 5 is a schematic of a stacked image sensor in accordance with another embodiment of the invention.

FIG. 6A is a schematic of a stacked image sensor in accordance with another embodiment of the invention.

FIG. 6B is a schematic of a stacked image sensor in accordance with another embodiment of the invention.

FIG. 6C is a schematic of a stacked image sensor in accordance with another embodiment of the invention.

FIG. 7A is a schematic of a stacked image sensor in accordance with another embodiment of the invention.

FIG. 7B is a schematic of a stacked image sensor in accordance with another embodiment of the invention.

FIG. 8 is a schematic diagram of a shared processing and amplification architecture that can be implemented in an image sensor having two semiconductor dies in an embodiment in accordance with the invention.

FIG. 9 is a schematic diagram illustrating the structure in which a given floating diffusion region in a sensor die is shared by four photodiodes of that sensor die according to an embodiment of the invention.

FIG. 10 is a timing diagram showing the operation of the image sensor of FIG. 7A.

FIG. 11 is a timing diagram showing the read out operation of the image sensor of FIG. 7B.

FIG. 12 is a timing diagram illustrating the operation of the image sensor according to an embodiment of the invention.

FIG. 13 is a timing diagram illustrating the operation of the image sensor according to another embodiment of the invention.

### DETAILED DESCRIPTION

As will be discussed below, the disclosed embodiments allow for larger light sensitive elements in spite of shrinking image sensor circuit features through the use of a stacked configuration of sensor and circuit dies. Further, some of the disclosed embodiments achieve a stacked image sensor without requiring a floating diffusion region on the circuit die. Floating diffusion region is a combination of diffusion areas like drain of transfer transistor, source of reset transistor and parasitic capacitors associated with.

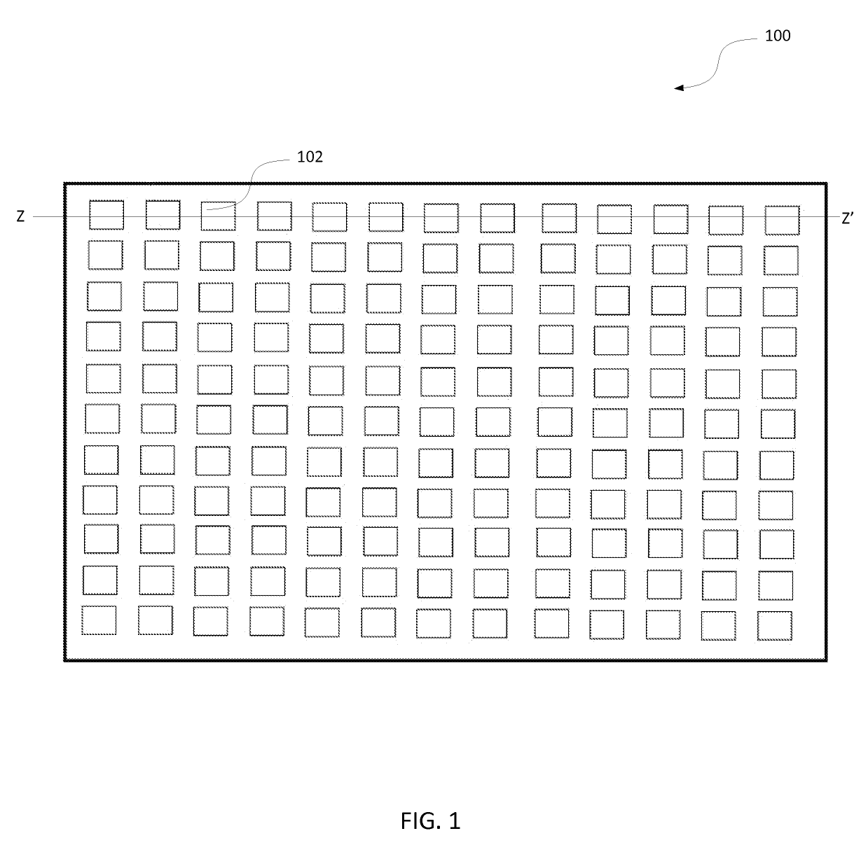

FIG. 1 is a plan view of a sensor die portion of an image sensor having two stacked semiconductor dies according to an embodiment of the invention. Image sensor 100 is implemented as an active pixel sensor (APS), such as, for example, a CMOS image sensor. Image sensor 100 includes pixels 102 arranged in an array of rows and columns. Image sensor 100 can have any number of pixels regions, such as, for example, 1280 columns by 960 rows of pixels.

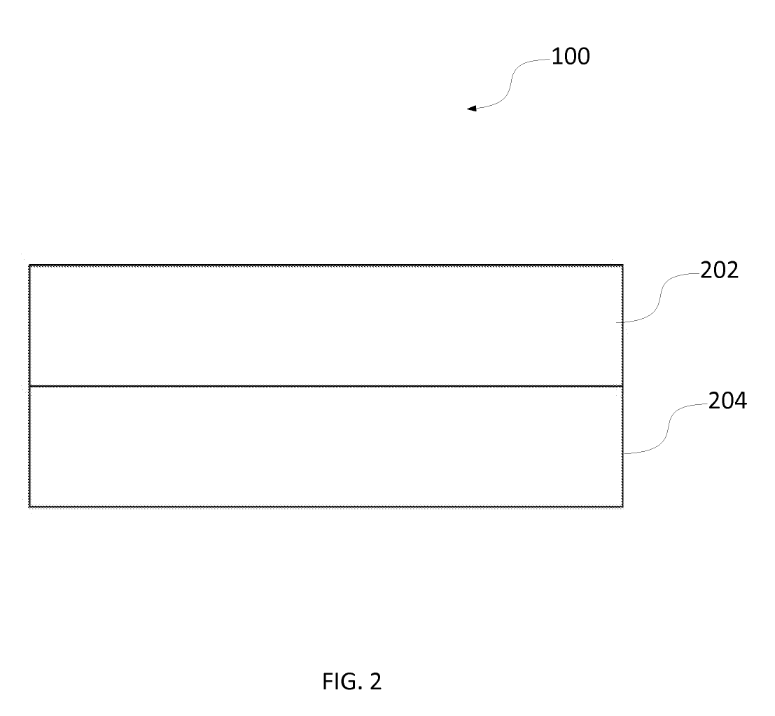

FIG. 2 is a cross-sectional view of two stacked semiconductor dies forming an image sensor of FIG. 1 along the section line Z-Z′. Image sensor 100 includes a sensor die 202 and a circuit die 204. In this view, it can be seen that the circuit die 204 is communicatively coupled to the sensor die 202. For example, the circuit die 204 may underlie the sensor die 202.

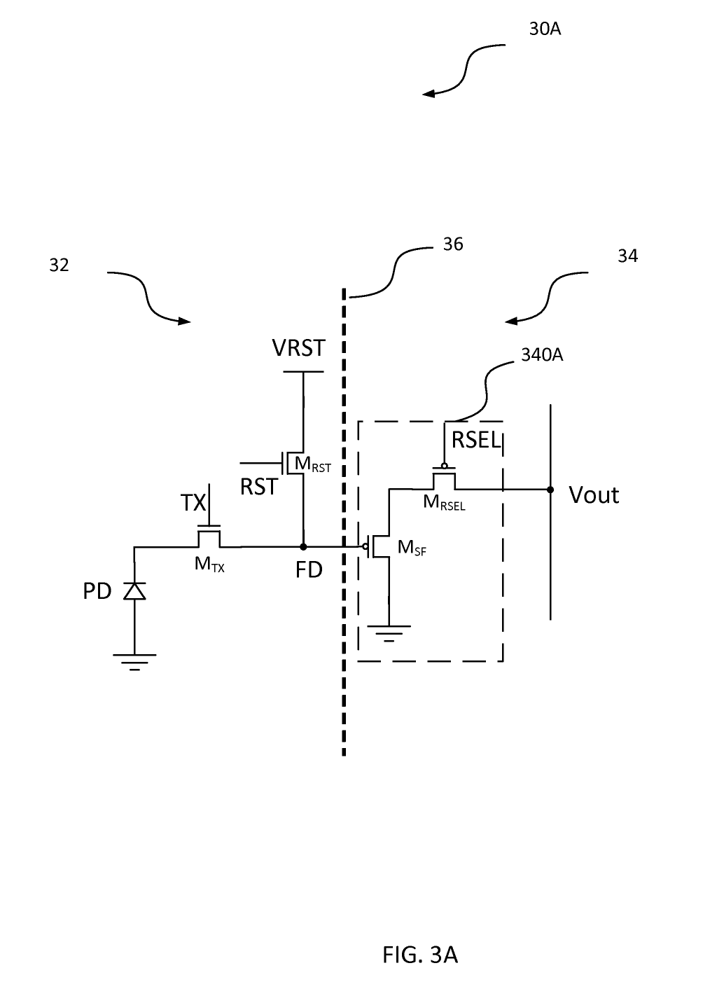

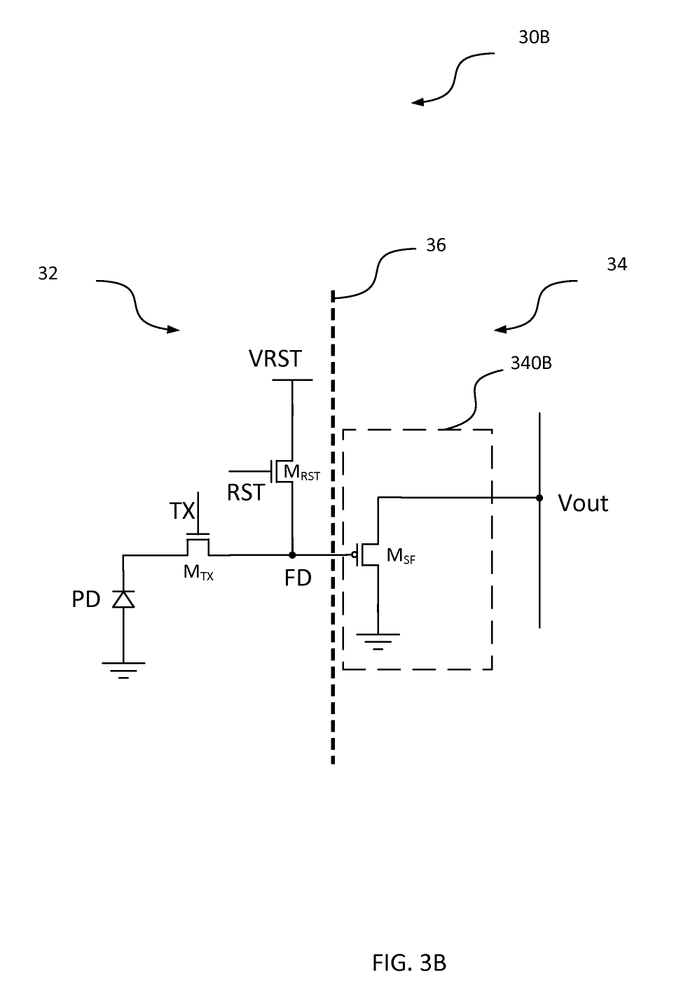

FIG. 3A is a schematic diagram of a stacked image sensor with a floating diffusion region in a sensor die according an embodiment of the invention. An active pixel sensor 30 includes a sensor die 32 and a circuit die 34. The dotted line 36 represents a die border between two dies 32 and 24. Each sensor die 32 comprises a plurality of pixels. Each pixel includes a light sensitive element, a transfer gate M_{TX}, a floating diffusion region FD, a reset gate M_{RST,} and a voltage potential VRST. Note that VRST represents reset reference voltage, and it is not necessary a power signal. VRST could be just a fixed reference voltage. The reset gate M_{RST} resets the floating diffusion region FD to a fixed voltage. Note that a photodiode PD is shown in FIG. 3A as the light sensitive element, but it can be appreciated that other types of light sensitive elements can be easily substituted for the photodiode, such as a pinned photodiode, photogate, phototransistors, etc. Thus, the term photodiode, as used herein, shall mean any light sensitive element that can convert incident light into an electrical signal. The transfer gate M_{TX} is configured between the photodiode PD and the gate of the source follower M_{SF}. Both the transfer signal bus TX and the reset signal bus RST are located in the sensor die 32.

Each circuit die 34 comprises a plurality of processing and amplification circuits 340A associated with the reset gates M_{RST} of the sensor die 32. The sensor die 32 is interconnected with the circuit die 34 utilizing a plurality of inter-die interconnects (not shown in FIG. 3A) each coupled to a source node of a reset gate M_{RST} on the sensor die 32 and a node of a processing and amplification circuit 340A on the circuit die 34.

Alternatively, the processing and amplification circuit 340A comprises a source follower transistor M_{SF} and a row selector transistor M_{RSEL,} wherein a drain of the row selector transistor M_{RSEL} is connected to a source of source follower transistor M_{SF}. A source of the row selector transistor M_{RSEL} is connected to output (VOUT). The source follower transistor M_{SF} amplifies the signal on the floating diffusion region FD when the signal on the floating diffusion region FD is to be read out. The source follower transistor M_{SF} and the row selector transistor M_{RSEL} use PMOS, and a drain of the row selector transistor M_{RSEL} is connected to a source of the source follower transistor M_{SF}. A source of the row selector transistor M_{RSEL} is connected to the output signal VOUT. A drain of the source follower transistor M_{SF} is connected to ground.

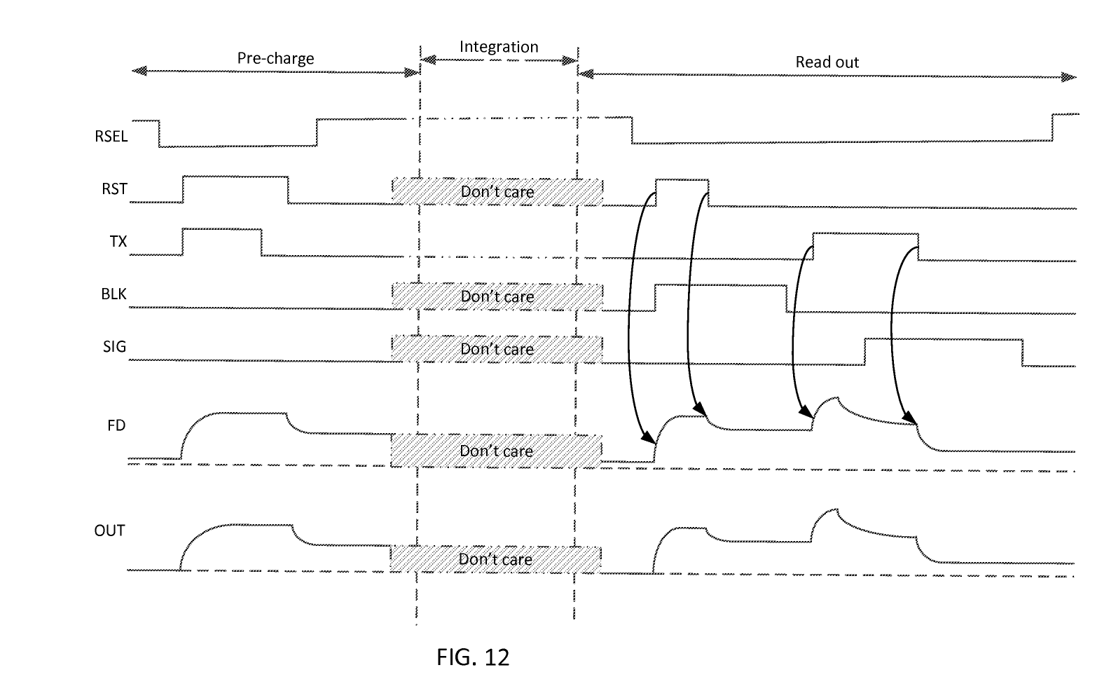

FIG. 12 shows a timing for the operation of the image sensor 100. There are three periods in general.

First, in the Pre-charge (or reset) period. The reset gate M_{RST} is on, the transfer gate M_{TX} is on, photodiode PD is reset to full depletion. Then the transfer gate M_{TX} is off followed by the turning off of the reset gate M_{RST}.

Then comes the integration period. Basically the transfer gate M_{TX} is off in the integration period. The reset gate M_{RST} can be on so floating diffusion region FD is connected to VRST so as to reduce overflow. The reset gate M_{RST} can be off too. Basically status of the floating diffusion region FD will not impact the function of pixel.

Then follows the Readout period. The row selector transistor M_{RSEL} is on, which is used to select the line to read out. As M_{RSEL} employs a PMOS, when the row selector transistor M_{RSEL} is at high voltage, it means that the row selector transistor M_{RSEL} is off, and when the row selector transistor M_{RSEL} is at low voltage, it means that the row selector transistor M_{RSEL} is on. The row selector transistor M_{RSEL} is turned on briefly to allow the signal output by the source follower transistor M_{SF} to be placed on the readout line VOUT. An image sensor is read out one row at a time. That means that only one row selector transistors M_{RSEL} in the whole image array are “on” at any point in time. All the other rows have their M_{RSEL} transistors turned “off”. Then the reset gate M_{RST} is on to reset the floating diffusion region FD. A signal BLK is on to store a black reference signal. The reset gate M_{RST} is off before the signal BLK is off so that the kTC noise generated by the reset gate M_{RST} turning off will be stored. Then the transfer gate M_{TX} is on, which enables transfer charge from the photodiode PD to the floating diffusion region FD. Then the SIG is on to store signal. The transfer gate M_{TX} is off before SIG is off so the charge injection of the transfer gate M_{TX} will not be stored.

However, the row selector transistor M_{RSEL} is optional. The function of M_{RSEL} is to connect the source of source follower M_{SF} to output bus VOUT when the row is selected for pre-charge or read out, and disconnect the source of source follower M_{SF} to output bus VOUT when the row is not selected for pre-charge or read out. When the row selector transistor M_{RSEL} is omitted, the source follower M_{SF} can act as a row select device when the row is not selected.

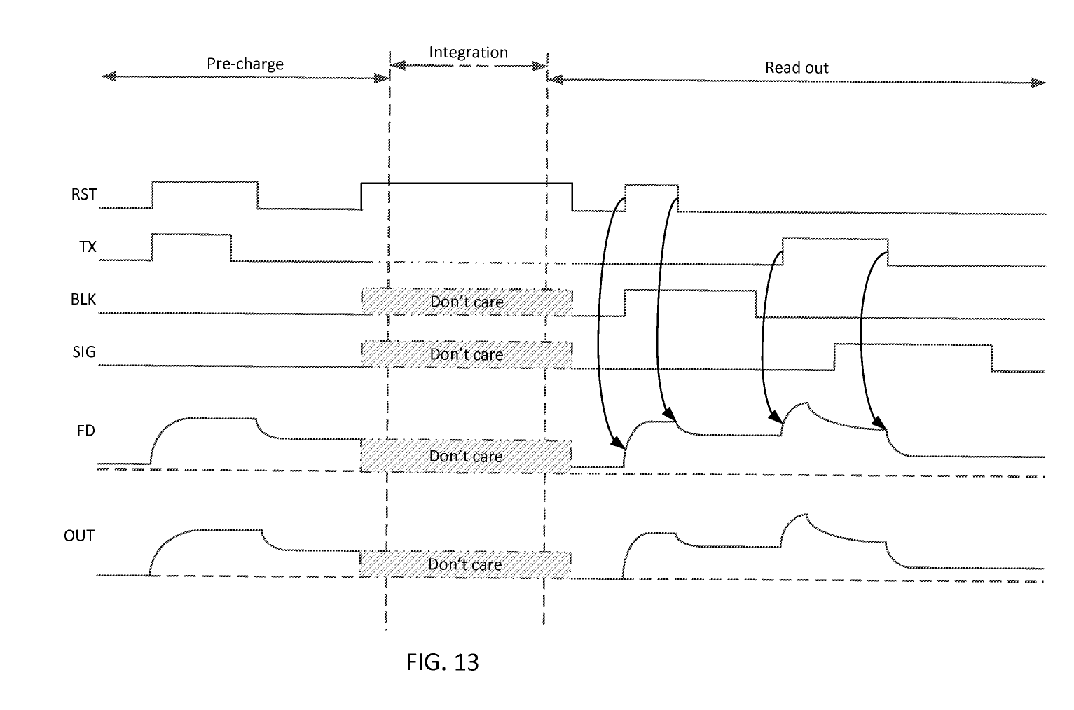

FIG. 3B is a schematic of a stacked image sensor in accordance with another embodiment of the invention. In FIG. 3B, the row selector transistor M_{RSEL} is omitted. That is a processing and amplification circuit 340B comprises a source follower M_{SF}. Biasing the floating node to a voltage above source follower threshold voltage, the source follower transistor M_{SF} will be “off”. The floating node voltage is above source follower threshold voltage when reset transistor M_{RST} is “on”. A signal RST is high when the row is not selected. Floating node is high voltage that turns off source follower M_{SF}. FIG. 13 is the timing for this embodiment.

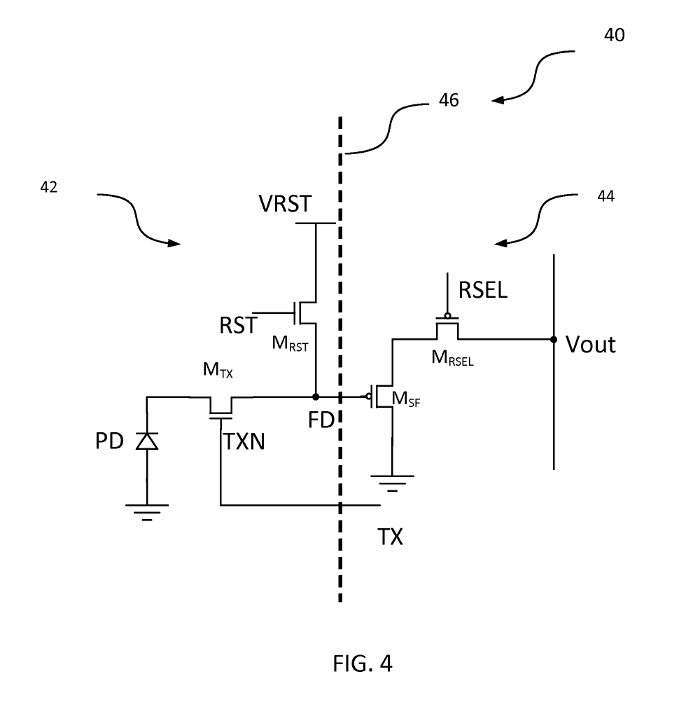

FIG. 4 is a schematic of a stacked image sensor in accordance with another embodiment of the invention. In FIG. 4, an active pixel sensor 40 includes a sensor die 42 and a circuit die 44, wherein same reference signs represent same elements in the active pixel sensor 30 shown in FIG. 3A, the detail descriptions of which are omitted. The dotted line 46 represents a die border between two dies 32 and 24. As shown in FIG. 4, the transfer signal bus TX is located in the circuit die 44, so as to save space on the sensor die 42 for accommodating a larger photo detector on the sensor die 42. In other words, the transfer node TXN on the sensor die 42 is interconnected to the transfer signal bus TX in the circuit die 44.

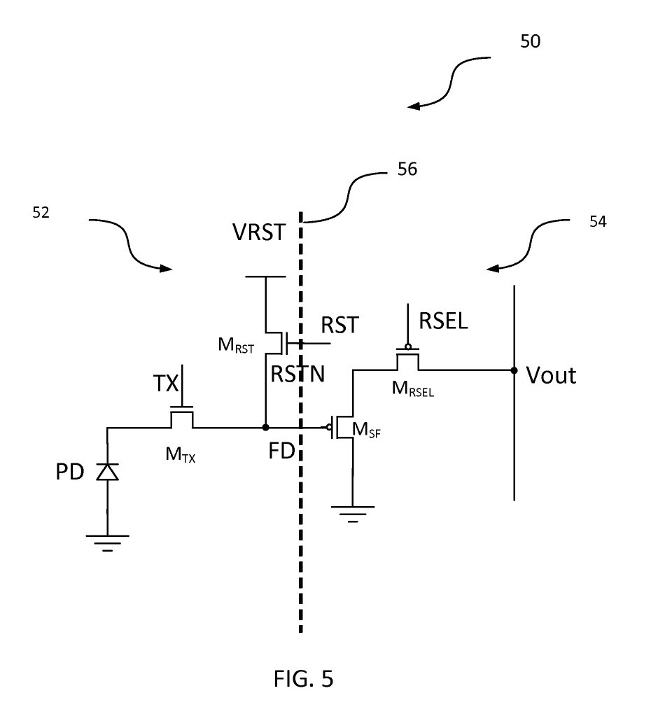

FIG. 5 is a schematic of a stacked image sensor in accordance with another embodiment of the invention. In FIG. 5, an active pixel sensor 50 includes a sensor die 52 and a circuit die 54, wherein same reference signs represent same elements in the active pixel sensor 30 shown in FIG. 3A, the detail descriptions of which are omitted. The dotted line 56 represents a die border between two dies 52 and 54. As shown in FIG. 5, the reset bus RST is located in the circuit die 54, so as to save space on the sensor die 52 for accommodating a larger photo detector on the sensor die 52. In other words, the reset node RSTN on the sensor die 52 is interconnected to the reset signal bus RST in the circuit die 54.

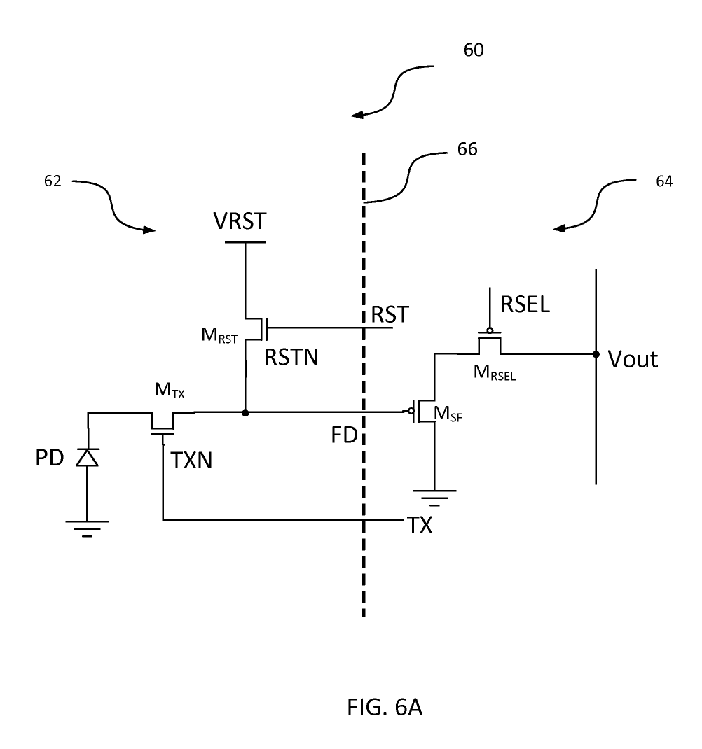

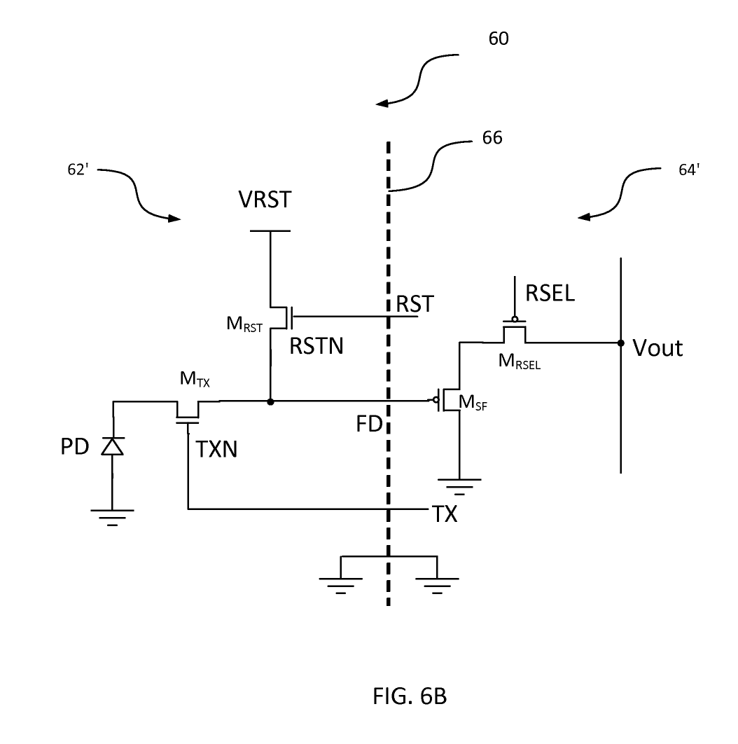

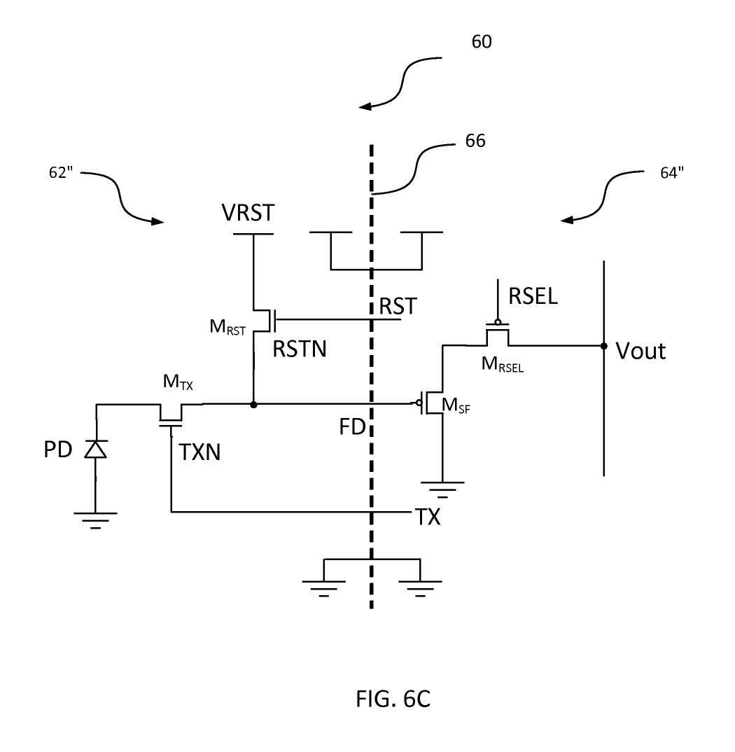

FIG. 6A is a schematic of a stacked image sensor in accordance with another embodiment of the invention. In FIG. 6A, an active pixel sensor 60 includes a sensor die 62 and a circuit die 64, wherein same reference signs represent same elements in the active pixel sensor 30 shown in FIG. 3A, the detail descriptions of which are omitted. The dotted line 66 represents a die border between two dies 62 and 64. As shown in FIG. 6A, both the reset signal bus RST and the transfer signal bus TX are located in the circuit die 64, so as to save space on the sensor die 62 for accommodating a larger photo detector on the sensor die 62. In other words, the reset node RSTN on the sensor die 62 is interconnected to the reset signal bus RST in the circuit die 64, and the transfer node TXN on the sensor die 62 is interconnected to the transfer signal bus TX in the circuit die 44.

FIG. 6B is a schematic of a stacked image sensor in accordance with another embodiment of the invention. The transfer gate M_{TX} is in the same die as the photodiode PD so to avoid contact requirements. The photodiode PD is surrounded with pure silicon crystal so to avoid defect which may lead to dark current, or defect pixel, etc. Unlike the ground bus shown in FIG. 6A, the ground bus in FIG. 6B is located in the circuit die 64′. There is ground connection between the sensor die 62′ and the circuit die 64′.

FIG. 6C is a schematic of a stacked image sensor in accordance with another embodiment of the invention. The transfer gate M_{TX} is in the same die as the photodiode PD so to avoid contact requirements. The photodiode PD is surrounded with pure silicon crystal so to avoid defect which may lead to dark current, or defect pixel, etc. Unlike the VRST bus shown in FIG. 6B, the VRST bus in FIG. 6C is located in the circuit die 64″. There is VRST connection between the sensor die 62″ and the circuit die 64″. Although not shown in FIG. 6C, there is no metal layer in the sensor die 62″, so as to reduce cost.

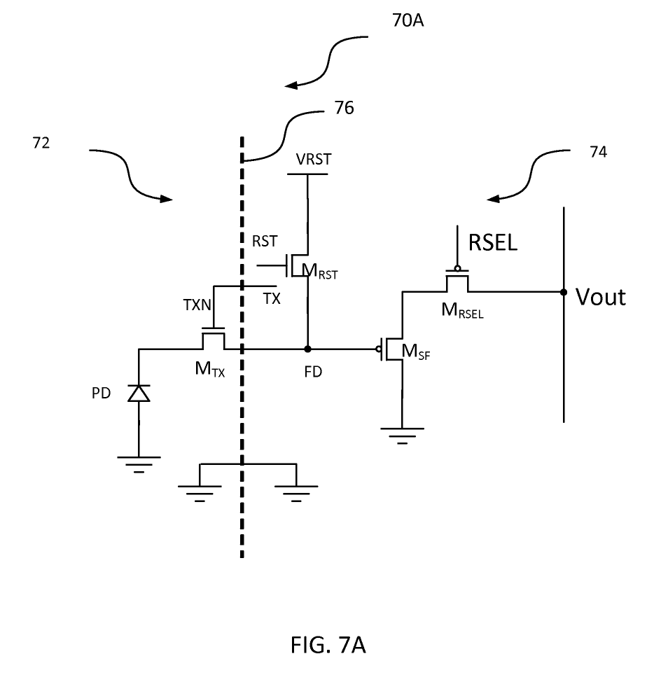

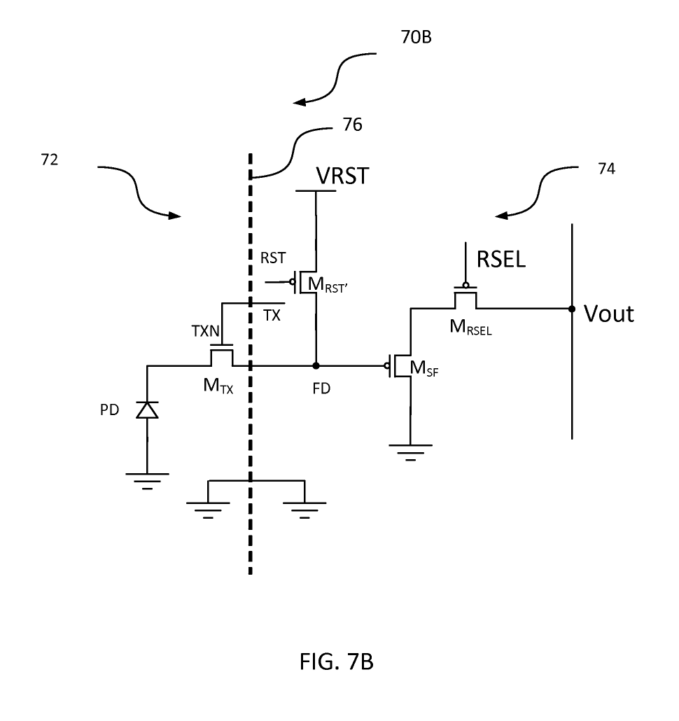

FIG. 7A is a schematic of a stacked image sensor in accordance with another embodiment of the invention. In FIG. 7A, an active pixel sensor 70A includes a sensor die 72 and a circuit die 74, wherein same reference signs represent same elements in the active pixel sensor 30 shown in FIG. 3A, the detail descriptions of which are omitted. The dotted line 76 represents a die border between two dies 72 and 74. The floating diffusion region FD is located both in sensor die 72 (drain of transfer transistor M_{TX} and associated parasitic capacitor) and in the circuit die 74. The reset signal bus RST is located in the circuit die 74, so as to save space on the sensor die 52 for accommodating a larger photo detector on the sensor die 52. As shown in FIG. 7A, the reset gate is a NMOS.

FIG. 7B is a schematic of a stacked image sensor 70B in accordance with another embodiment of the invention. In FIG. 7B, same reference signs represent same elements in the active pixel sensor 70A shown in FIG. 3A, the detail descriptions of which are omitted. As shown in FIG. 7B, the reset gate M_{RST} is a PMOS.

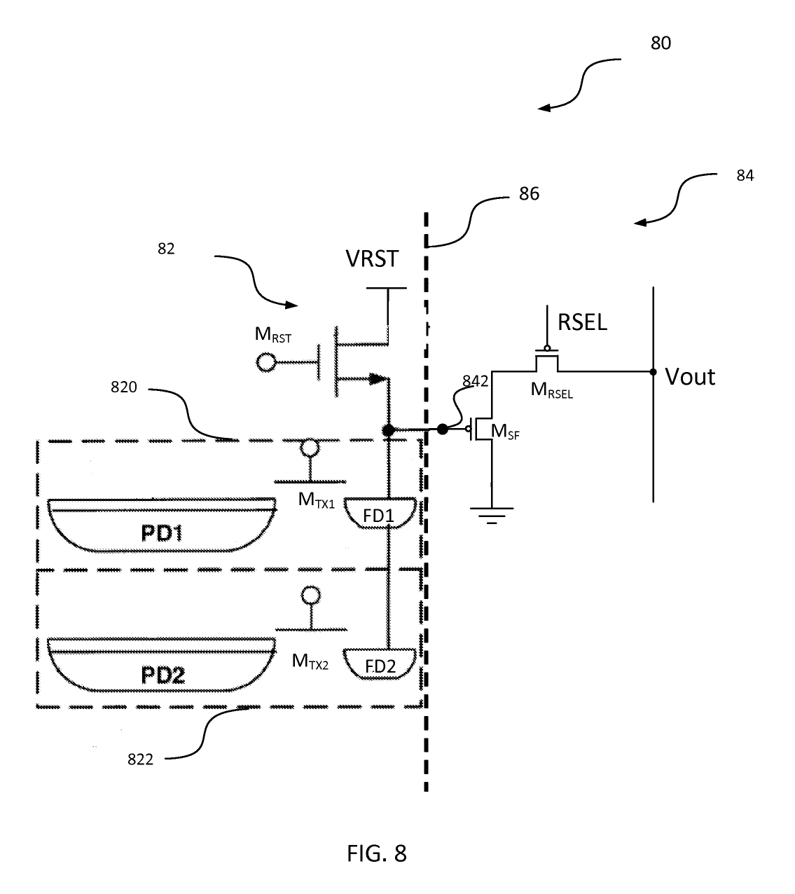

As shown in both FIG. 7A and 7B, the TX signal bus is located on the circuit die 74, and the transfer node TXN on the sensor die 72 is interconnected to the transfer signal bus TX in the circuit die 74. Referring now to FIG. 8, there is shown a schematic diagram of a shared processing and amplification architecture that can be implemented in an image sensor having two semiconductor dies in an embodiment in accordance with the invention.

An image sensor utilizing this architecture includes a sensor die 82 with pixels that include a first photodiode PD1, a first transfer gate M_{TX1}, a first floating diffusion region FD1, a second photodiode PD2, a second transfer gate M_{TX2}, and a second floating diffusion region FD2. The first photodiode PD1, the first transfer gate M_{TX1,} and the first floating diffusion region FD1 are associated with a first pixel 820 while the second photodiode PD2, the second transfer gate M_{TX2}, and the second floating diffusion region FD2 are associated with a second pixel 822. Although only two pixels 820, 822 are shown in FIG. 8, an image sensor can include additional pixels in an embodiment in accordance with the invention.

Each pixel has its own photodiode, and the two pixels 820, 822 share a reset gate M_{RST}. The two pixels 820, 822 further share a processing and amplification circuit in the circuit die 84. Each of the pixels has its output going to the same shared processing and amplification circuitry in the circuit die 84. Both first and second floating diffusion regions FD1 and FD2 on the sensor die 82 are connected electrically to node 842 on the circuit die 84 using inter-die contact in an embodiment in accordance with the invention. Although the first and second floating diffusion regions FD1 and FD2 shown in FIG. 8 are separate, those having ordinary skill in the art understand that the first and second floating diffusion regions FD1 and FD2 can be an integrated one and shared by the first photodiode PD1 and the second photodiode PD2, which may result in less defects, higher conversion gain. Every two pixels share a same reset gate M_{RST} and a same processing circuitry. As the shared processing circuitry is on another separate circuit die 84, the sensor die 82 needs to convey the signal over to the circuit die 84. The signal is conveyed using a floating node. It is the back end processing circuitry that is shared by a plurality of pixels on a sensor die.

As shown in FIG. 7A or 7B, the ground signal bus is located on the circuit die 74, and the substrate contacts of the sensor die 72 are interconnected to the ground signal bus in circuit die 74.

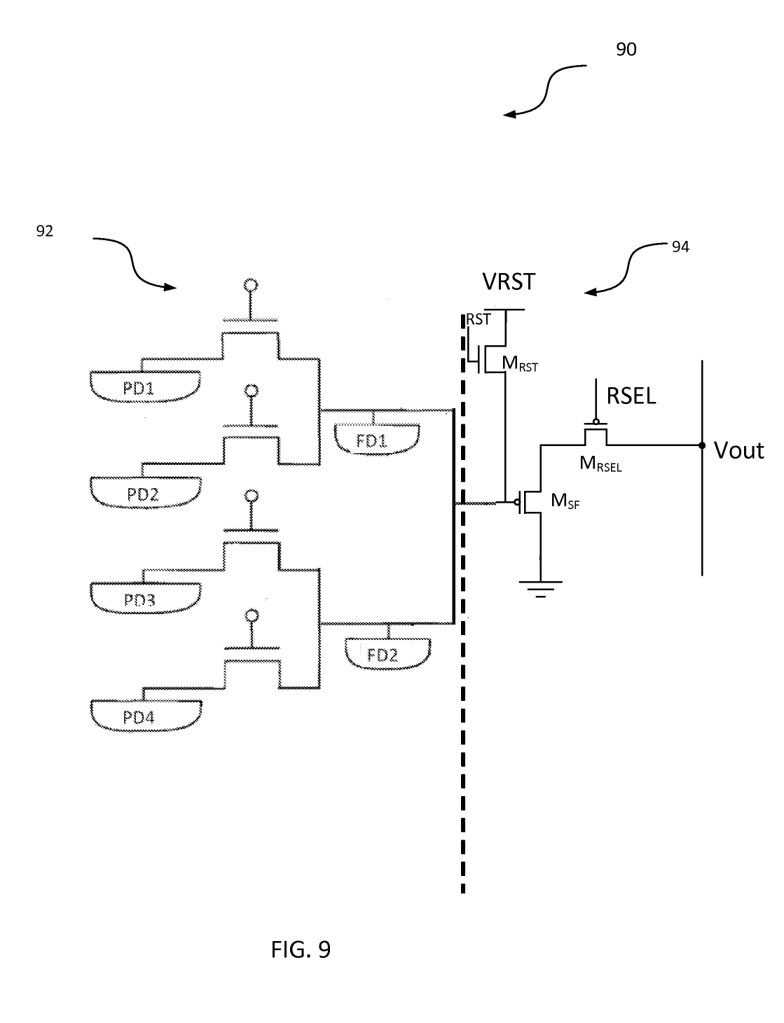

Those having ordinary skill in the art can understand that one substrate contact within every 1, 2, 4, or N×M pixels can also be applied to the embodiments of the invention, as will be discussed below with reference to FIG. 9. As every 2 or 4 or 8 pixels might share the readout and amplification transistors, it lowers the amount of inter-die contact between circuit die and sensor die that will make manufacturing process easier.

Although in the above embodiment the interconnections between layers are realized by vias, those having ordinary skill in the art can understand that inductive coupling, capacitive coupling, and/or optical coupling can also be implemented as an inter-layer interconnection. Some sensors use silicon-on-insulator (SOI) and silicon-on-sapphire (SOS) technologies, which make it easy to bond two dies.

As shown in the schematic diagram of FIG. 9, photodiodes PD1 and PD2 share a common first floating diffusion region FD1, and photodiodes PD3 and PD4 share a common second floating diffusion region FD2. Each of the photodiodes PD1, PD2, PD3 and PD4 has an associated transfer gate M_{TX1}, M_{TX2}, M_{TX3} and M_{TX4} respectively. The four transfer gates M_{TX1}, M_{TX2}, M_{TX3} and M_{TX4} couple the respective photodiodes to the shared floating diffusion region FD1 or FD2.

Both of the floating diffusion regions FD1 and FD2 of the sensor die 92 are coupled to a processing and amplification circuitry for processing signals generated by the photodiodes PD1, PD2, PD3 and PD4. This additional circuitry comprises a reset gate M_{RST}, a source follower transistor M_{SF}, and a row selector transistor M_{RSEL.} This processing and amplification circuitry is coupled between a ground and an output voltage VOUT. It is apparent from FIG. 9 that the set of processing and amplification circuitry is shared by the four photodiodes PD1, PD2, PD3 and PD4 of the sensor die 92.

Alternatively or in addition, several pixels can share substrate interconnection via, so as to reduce total interconnection via number.

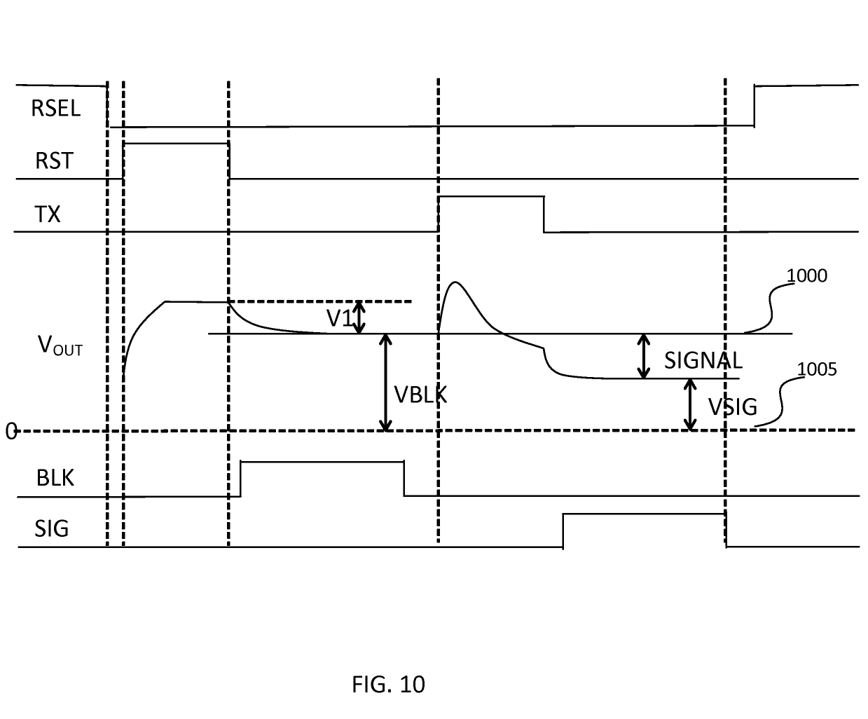

FIG. 10 is a timing diagram showing the read out operation of the image sensor of FIG. 7A. In FIG. 10, the vertical axis represents voltage of each signal, while the horizontal axis represents time. In FIG. 10, the row selector signal RSEL, the reset signal RST, the transfer signal TX are pulsed. The row selector signal RSEL is first pulsed to select a pixel. Then the reset gate RST is pulsed to reset the signal on the floating diffusion region FD. After reset signal RST returns to low, the signal on the floating diffusion region FD is read out and stored. The readout signal from the floating diffusion region FD is called a black signal, and is represented as BLK in FIG. 10. The stored voltage is represented as VBLK. The transfer signal TX is pulsed to trigger transfer of charge from the photodiode PD to the floating diffusion region FD. After the transfer signal TX returns to low, the signal on the floating diffusion region FD is read out and stored. The readout signal from the floating diffusion region FD is called a signal, and is represented as SIG in FIG. 10. The stored voltage is represented as VSIG.

The difference of VSIG and VBLK is the signal of photodiode after correlated double sampling (CDS), which is represented as SIGNAL, SIGNAL=VBLK−VSIG. The above subtraction cancels the threshold variation of source follower, and kTC noise of reset. The kTC noise is a thermal noise.

VOUT is the voltage on the VOUT signal bus. Note that all the other signals shown in FIG. 10, for example, row selector signal RSEL, the reset signal RST, the transfer signal TX, the black signal BLK and the signal SIG are in the digital domain, except the output signal VOUT which is in the analog domain. In FIG. 10, V1 is the charge injection when the reset transistor M_{RST} turns off, that is from high to low. VOUT is the output voltage of the row selector transistor M_{RSEL}.

VFD_MAX represents the maximum possible usable voltage at the floating diffusion region FD. When the reset signal RST is high, VFD_MAX equals VRST−VTH_M_{RST}, wherein VTH_M_{RST} represents the threshold of the reset gate M_{RST.} After the reset signal RST is off, VFD_MAX equals “VRST−VTH_M_{RST}−V1”. Therefore, the maximum usable signal at the floating diffusion region FD is “VRST−VTH_M_{RST}−V1.”

As the row selector transistor M_{RSEL} is always switched off except when the signal is in readout and pre-charge period, VOUT equals the source voltage of the source follower transistor M_{SF}. VOUT=VFD−VTH_M_{SF}. Line 1000 represents the stable signal level after reset. Line 1005 represents the ground 0. The output signal VOUT gradually reduces to VFD−VTH_M_{SF}, that is VRST−VTH_M_{RST}−V1−VTH_M_{SF}. As the reset gate M_{RST} uses NMOS, the reset gate M_{RST} voltage is high to reset the floating diffusion region FD, and the reset gate M_{RST} voltage changes from high to low to end reset. The parasitic capacitance between the reset gate M_{RST} and the floating diffusion region FD causes the floating diffusion region FD signal, and then the output voltage VOUT to decrease. Then the signal VOUT is stabilized at VBLK. Then as the transfer gate M_{TX} switches on, the voltage of the floating diffusion region FD, so does the output voltage VOUT, experience a voltage spike. Then, after the transfer gate M_{TX} returns to low, the signal of photodiode equals the difference of VBLK−VSIG.

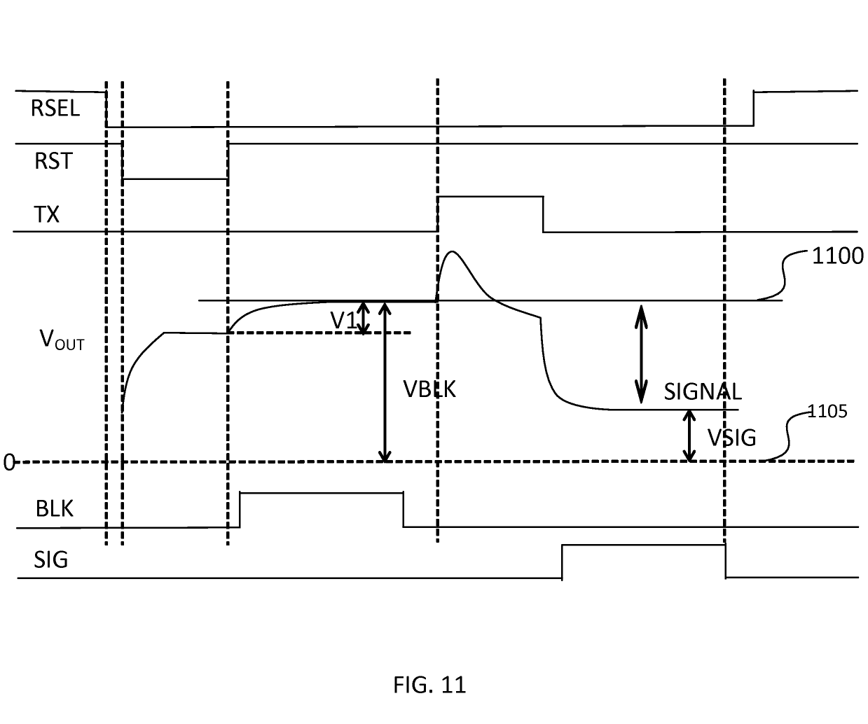

FIG. 11 is a timing diagram showing the read out operation of the image sensor of FIG. 7B. In FIG. 7B, the reset gate M_{RST} uses a PMOS.

In FIG. 11, V1 is the charge injection when the reset transistor M_{RST} turns off, that is from low to high. VOUT is the output voltage of the row selector transistor M_{RSEL}.

VFD_MAX represents the maximum possible usable voltage at the floating diffusion region FD. When the reset signal RST is low, VFD_MAX equals VRST. After the reset signal RST is off, VFD_MAX equals “VRST+V1”. Therefore, the maximum usable signal at the floating diffusion region FD is “VRST+V1.”

As the row selector transistor M_{RSEL} is always switched off except when the signal is in readout and pre-charge period, VOUT equals the source voltage of the source follower transistor M_{SF}. VOUT=VFD−VTH_M_{SF}. Line 1100 represents the stable signal level after reset. Line 1105 represents the ground 0. The output signal VOUT gradually increases to VFD−VTH_M_{SF}, that is VRST+V1−VTH_M_{SF}. As the reset gate M_{RST} uses PMOS, the reset gate M_{RST} voltage is low to reset the floating diffusion region FD, and the reset gate M_{RST} voltage changes from low to high to end reset. The parasitic capacitance between the reset gate M_{RST} and the floating diffusion region FD causes the floating diffusion region FD signal, and then the output voltage VOUT to increase. Then the signal VOUT is stabilized at VBLK. Then as the transfer gate M_{TX} switches on, the voltage of the floating diffusion region FD increases, so does the output voltage VOUT, experience a voltage spike or glitch. Then, after the transfer gate M_{TX} returns to low, the signal of photodiode SIGNAL equals the difference of VBLK−VSIG.

Note that the transfer gate M_{TX} is a NMOS, while the source follower transistor M_{SF} is a PMOS. The mixture of NMOS and PMOS will take a significant amount of area. Therefore the transfer gate M_{TX} and the source follower transistor M_{SF} need to be separated in two dies so as to save room to accommodate a photodiode as large as possible. As a result a fill factor, which is the ratio of the active refracting area, i.e. that area which directs light to the photo sensor, to the total contiguous area occupied by the microlens array, can be kept as large as possible.

Further, in a CMOS process, a NMOS is inside a PWELL, which means the NMOS substrate is P type, and a PMOS is inside an NWELL, which means the PMOS substrate is N type. Only when the reset transistor, transfer transistor, and source follower all use NMOS can they be in the same type substrate or same PWELL. Similarly, only when the reset transistor, transfer transistor, and source follower all use PMOS can they be in the same type substrate or same NWELL. A separate NWELL is needed if the source follower is PMOS, while at least one of the other gates is NMOS. Different well requires very large space and it is impossible to have two type of WELLs within pixel in today's small pixel. Therefore, the PMOS and the NMOS need to be separated in two dies.

With the use of PMOS as source follower transistor, the flicker noise, also commonly known as 1/f noise since the noise spectral density is inversely proportional to frequency, can be reduced compared to using NMOS as the source follower transistor. Further, the random telegraph signal noise (RTS noise) can be reduced using PMOS as the source follower transistor.

Features and aspects of various embodiments may be integrated into other embodiments, and embodiments illustrated in this document may be implemented without all of the features or aspects illustrated or described. One skilled in the art will appreciate that although specific examples and embodiments of the system and methods have been described for purposes of illustration, various modifications can be made without deviating from the spirit and scope of the present invention. For example, embodiments of the present invention may be applied to image sensors having different types of light sensing devices, such as photodiodes, photogates, pinned photodiodes, and equivalents. Moreover, features of one embodiment may be incorporated into other embodiments, even where those features are not described together in a single embodiment within the present document. Accordingly, the invention is described by the appended claims.

I/we claim:

1. An active pixel sensor comprising:
a sensor die comprising
a plurality of pixels, wherein each pixel includes a light sensitive element and a transfer gate, a floating diffusion region, wherein the plurality of pixels include at least one reset gate; and
a circuit die comprising a plurality of processing and amplification circuits associated with the reset gates of the sensor die;
wherein the sensor die is interconnected with the circuit die utilizing a plurality of inter-die interconnects each coupled to a source node of a reset gate on the sensor die and a node of a processing and amplification circuit on the circuit die; the plurality of processing and amplification circuits each comprises a source follower transistor, wherein the source follower transistor uses a PMOS.

2. The active pixel sensor of claim 1, wherein the plurality of processing and amplification circuits each further comprises a row selector transistor, wherein the row selector transistor uses a PMOS, and a drain of the row selector transistor is connected to a source of the source follower transistor.

3. The active pixel sensor of claim 1, wherein the circuit die does not include a floating diffusion area.

4. The active pixel sensor of claim 1, wherein each inter-die interconnects further couples the floating diffusion region on the sensor die and the node of the processing and amplification circuit on the circuit die.

5. The active pixel sensor of claim 1, wherein a plurality of pixels share one reset gate.

6. The active pixel sensor of claim 1, wherein a plurality of pixels share one processing and amplification circuit.

7. The active pixel sensor of claim 1, wherein the transfer gate is controlled by a transfer signal bus on the circuit die.

8. The active pixel sensor of claim 1, wherein the transfer gate is controlled by a transfer signal bus on the sensor die.

9. The active pixel sensor of claim 1, wherein the reset gate is controlled by a reset signal bus on the sensor die.

10. The active pixel sensor of claim 1, wherein the reset gate is controlled by a reset signal bus on the circuit die.

11. The active pixel sensor of claim 1, a ground of the sensor die is connected to a ground signal bus located in the circuit die.

12. The active pixel sensor of claim 1, wherein a reset reference voltage for the reset gate is controlled by a reset reference voltage bus on the circuit die.

13. The active pixel sensor of claim 1, wherein the floating diffusion region collects charge from a pixel of the sensor die.

14. The active pixel sensor of claim 1, wherein the floating diffusion region collects charge from a plurality of pixels of the sensor die.

15. The active pixel sensor of claim 1, wherein the reset gate resets the charge collected at a floating diffusion region.

16. The active pixel sensor of claim 1, wherein the reset gate resets the charge collected at a plurality of floating diffusion region of the sensor die.

17. The active pixel sensor of claim 1, wherein the light sensitive element comprises a photodiode.

18. An active pixel sensor comprising:
a sensor die comprising
a plurality of pixels, wherein each pixel includes a light sensitive element and a transfer gate, a plurality of floating diffusion regions associated with the plurality of transfer gate;
a circuit die comprising
a plurality of floating diffusion regions associated with a plurality of reset gate and a plurality of processing and amplification circuits;
wherein the sensor die is interconnected with the circuit die utilizing a plurality of inter-die interconnects each coupled to a drain node of a transfer gate on the sensor die and a node of a floating diffusion region on the circuit die; the plurality of processing and amplification circuits each comprises a source follower transistor, wherein the source follower transistor uses a PMOS.

19. The active pixel sensor of claim 18, wherein the plurality of processing and amplification circuits each further comprises a row selector transistor, wherein the row selector transistor uses a PMOS, and a drain of the row selector transistor is connected to a source of the source follower transistor.

20. The active pixel sensor of claim 18, wherein the floating diffusion region collects charge from a pixel of the sensor die.

21. The active pixel sensor of claim 18, wherein the floating diffusion region collects charge from a plurality of pixels of the sensor die.

22. The active pixel sensor of claim 18, wherein the reset gate resets the charge collected at a floating diffusion region.

23. The active pixel sensor of claim 18, wherein the reset gate resets the charge collected at a plurality of floating diffusion region.

24. The active pixel sensor of claim 18, wherein the reset gate uses a PMOS.

25. The active pixel sensor of claim 18, wherein the reset gate uses a NMOS.

26. The active pixel sensor of claim 18, wherein the light sensitive element comprises a photodiode.

27. The active pixel sensor of claim 18, wherein a plurality of pixels share one reset gate.

28. The active pixel sensor of claim 18, wherein a plurality of pixels share one processing and amplification circuit.

29. The active pixel sensor of claim 18, wherein the transfer gate is controlled by a transfer signal bus on the circuit die.

30. The active pixel sensor of claim 18, wherein the transfer gate is controlled by a transfer signal bus on the sensor die.

31. The active pixel sensor of claim 18, wherein the reset gate is controlled by a reset signal bus on the circuit die.

32. The active pixel sensor of claim 18, a ground of the sensor die is connected to a ground signal bus located in the circuit die.

33. The active pixel sensor of claim 1, wherein a reset reference voltage for the reset gate is controlled by a reset reference voltage bus on the circuit die.
